(19) United States
(12) Patent Application Publication
(10) Pub. No.: US 2007/0114538 A1
(43) Pub. Date: May 24, 2007

(54) Light-emitting semiconductor devices having variable emission wavelengths

(75) Inventors: Fariba Hatami, Berlin (DE); William Ted Masselink, Berlin (DE)

Correspondence Address: ROTHWELL, FIGG, ERNST & MANBECK, P.C., 1425 K STREET, N.W., SUITE 800, WASHINGTON, DC, 20005, US

(73) Assignee: HUMBOLDT-UNIVERSITAET ZU BERLIN, Berlin (DE)

(21) Appl. No.: 10/584,882

(22) PCT Filed: Dec. 24, 2004
(86) PCT No.: PCT/EP04/14713

§ 371 Date: Jun. 29, 2006

(30) Foreign Application Priority Data
Jan. 8, 2004 (DE) 10 2004 001 823.5

(51) Int. Cl. H01L 31/0256

(52) U.S. Cl. 257/76; 977/700

(57) ABSTRACT

An inventive semiconductor device for emitting light when applying a voltage comprises: a first semiconductor region (3) whose conductivity is based on charge carriers of a first type of conductivity, e.g. electrons; a second semiconductor region (5) whose conductivity is based on charge carriers of a second type of conductivity, e.g. holes, which have a charge opposite that of the charge carriers of the first type of conductivity and; an active semiconductor region (7A 7C), which is situated between the first semiconductor region (3) and the second semiconductor region (5) and in which the emission of light occurs, these regions being embedded in the quantum structures (13, 15) of a semiconductor material having a direct band gap in at least two different intercoupled configurations. In addition, a switching device (20) for directly or indirectly influencing the current flowing through the active semiconductor region (7A 7C) is assigned to the inventive semiconductor device and is designed for switching back and forth at least between a current flowing through the active semiconductor region with a current intensity (H1) less than a specified threshold current intensity and a current flowing through the active semiconductor region with a current intensity (H2) greater than the threshold current intensity.

The present invention concerns a light-emitting semiconductor device having a variable emission wavelength and a method of producing colored light with such a semiconductor device.

Light-emitting semiconductor devices nowadays represent key components inter alia in devices for transmitting information, in memory devices, in display devices and in lighting devices. Semiconductor devices which light up in the visible spectral range however do not afford high levels of light intensity. Thus the first light emitting diodes (LEDs) were able to provide just enough intensity to be used as display elements in early pocket calculators and digital clocks and watches.

Many light-emitting semiconductor devices in accordance with the state of the art, in particular LEDs, are based on gallium phosphide (GaP). It will be noted however that that material has only a low level of efficiency in light production. At the present time however there is a trend for semiconductor devices which emit light in the visible spectral range such as for example LEDs also to be used in areas in which a high level of light intensity is required. Thus automobile manufacturers are increasingly seeking to replace conventional lamps in a motor vehicle by LEDs. A further area of use involving semiconductor devices which emit light in the visible spectral range with a high level of light intensity is for example traffic lights in which red, green and amber emitters which provide a very intensive light are required. However it is not only in traffic and vehicle technology but also in information transmission that semiconductor devices which provide a high level of light intensity in the visible spectral range are to be profitably employed.

In addition it would be desirable in relation to many uses if the wavelength and therewith the color of the light delivered by the semiconductor device would be adjustable. With a semiconductor device, for example a LED, in which the color of the light produced would be adjustable, it would be possible to reduce for example the number of the necessary semiconductor devices or LEDs in display devices as it would no longer be necessary to provide for each color its own semiconductor device or LED.

Therefore an object of the present invention is to provide a light-emitting semiconductor device which not only affords a high level of lighting intensity but in which the emission wavelength of the light produced can also be altered.

A further object of the present invention is to provide an improved display device.

Finally an object of the present invention is to provide a method of adjusting the light delivered by a semiconductor device according to the invention.

The first object is attained by a semiconductor device as set forth in claim 1, the second object is attained by a display device as set forth in claim 12 and the third object by a method as set forth in claim 15. The appendant claims recite advantageous developments of the invention.

For better understanding of the invention, some properties and features of semiconductor materials will be described hereinafter before beginning to describe the invention.

The electrical behaviour of a semiconductor material can be described with what is referred to as the band model. That states that various energy ranges, referred to as the energy bands, are available to the charge carriers of the semiconductor material, within which they can assume substantially any energy values. Different bands are frequently separated from each other by a band gap, that is to say an energy range involving energy values which the charge carriers cannot assume. If a charge carrier moves from an energy band at a higher energy level into an energy band at a low energy level, energy is liberated, which corresponds to the difference of the energy values prior to and after the movement, which is also referred to as the ‘transition’. In that case the difference energy can be liberated in the form of light quanta (photons).

A distinction is drawn between what are referred to as direct and indirect band gaps. In the case of an indirect band gap, two processes must coincide so that a transition between the energy bands can take place, with the emission of light. Accordingly semiconductor materials with indirect band gaps such as for example GaP generally involve a much lower degree of efficiency when producing light than semiconductor materials with what are referred to as direct band gaps in which only one process is necessary for the emission of light.

In a semiconductor material negatively charged electrons and positively charged holes which can be imagined essentially as ‘missing’ electrons in an energy band are available as charge carriers. A hole can be filled by the transition of an electron from another energy band into the energy band in which the hole is present. The process of filling a hole is referred to as recombination. By introducing impurities, referred to as dopants, into the semiconductor material, it is possible to produce a predominance of electrons or holes as charge carriers. When there is a predominance of electrons, the semiconductor material is referred to as n-conducting or n-doped while when there is a predominance of holes as charge carriers it is referred to as p-conducting or p-doped. In addition the introduction of dopants can be used to influence the energy levels accessible or available to the charge carriers in the semiconductor material.

A semiconductor device according to the invention for emitting light when a voltage is applied comprises
a first semiconductor region whose conductivity is based on charge carriers of a first conductivity type, that is to say for example electrons,
a second semiconductor region whose conductivity is based on charge carriers of a second conductivity type, which have a charge opposite to the charge carriers of the first conductivity type, that is to say for example holes, and
an active semiconductor region which is arranged between the first semiconductor region and the second semiconductor region and in which the light emission takes place, in which quantum structures of a semiconductor material with a direct band gap are embedded in at least two different configurations which are coupled to each other.

In addition associated with the semiconductor device according to the invention is a switching device for directly or indirectly influencing the current flowing through the active semiconductor region, which is so designed that it is to be switched to and fro at least between a current flow through the active semiconductor region with a current intensity below a given threshold current intensity and a current flow through the active semiconductor region with a current intensity above the threshold current intensity.

The term quantum structures of the semiconductor device according to the invention is used to denote structures which in at least one direction of extent are of a dimension which is so small that the properties of the structure are substantially also determined by quantum-mechanical processes. The configurations of quantum structures that can be considered are quantum dots which represent quasi-zero-dimensional structures, quantum wires which represent quasi-one-dimensional structures and quantum wells which represent quasi-two-dimensional structures.

A semiconductor device of a structure according to the invention can emit in two different wavelengths. In that respect what wavelength is emitted can be influenced by means of the current intensity of the current flowing through the active region of the semiconductor device. If the current intensity exceeds a given threshold current intensity, light is emitted at the first wavelength, that is to say for example green light, whereas if the current intensity is below the threshold current intensity, that involves an emission of light at the second wavelength, that is to say for example red light. It is therefore possible to switch to and fro between the emission of light at the first wavelength and the emission of light at the second wavelength, by means of the associated switching device.

In addition the semiconductor structure according to the invention for the emission of light has a higher level of efficiency upon emission in the visible spectral range than light-emitting semiconductor structures in accordance with the state of the art. The reason for this is as follows:

Unlike the GaP-based light-emitting semiconductor devices in accordance with the state of the art the semiconductor device according to the invention makes it possible to use a direct transition between two energy bands for the emission of light in the visible spectral range. In that respect the direct transition takes place in the embedded quantum structures, the material of which is so selected that it has a direct band gap. As mentioned hereinbefore, the level of efficiency upon the emission of light in the case of a direct transition is higher than in the case of an indirect transition so that the level of efficiency of the semiconductor device according to the invention for emitting light when a voltage is applied is above that of light-emitting semiconductor devices in accordance with the state of the art. In that respect the quantum structures make it possible to influence the magnitude of the band gap which is used for light emission, in such a way that emission takes place in the visible spectral range.

In an advantageous development of the semiconductor device according to the invention quantum dots are selected as the first configuration of the quantum structures and a quantum well layer is selected as a second configuration of the quantum structures. Such a structure can be produced with suitable materials using what is referred to as Stranski-Krastanov growth. In the case of Stranski-Krastanov growth, a flat material layer is first formed at the beginning of the growth, which layer can be viewed as a quantum well structure if the growth conditions are so selected that the flat material layer does not exceed a thickness of a few nanometers (nm), the thickness preferably being in the range of between about 0.1 and about 0.3 nm. As from a given amount of material which is dependent on the material, the substrate and the ambient conditions in the growth, the growth then changes over to island growth, that is to say the newly arriving material forms on the flat layer mounds (referred to hereinafter as islands) which can be viewed as quantum dots if the growth conditions are so selected that the lateral extents of the islands on average are not more than about 50 nm and are preferably in the range of between about 10 and about 30 nm.

The Stranski-Krastanov growth can be particularly easily integrated into the production process of the semiconductor device according to the invention if the semiconductor regions are produced in the form of semiconductor layers of a layer stack.

In the semiconductor device according to the invention the first semiconductor region, the second semiconductor region and the active semiconductor region can each include AlₓGa₁₋ₓP (aluminum gallium phosphide) with 0≦x≦1. The quantum structures can be produced from a III-V semiconductor material, that is to say a semiconductor material which includes atoms in the third and fifth main groups of the periodic system, having a lattice constant which is greater than that of GaP. The lattice constant can be considered as a measurement in respect of how far the atoms in a crystalline material in which the atoms are arranged substantially at nodal points of a notional lattice are remote from each other.

The III-V semiconductor materials provide direct band gaps which, with suitably selected dimensions in respect of the quantum structures, can emit light in the visible spectral range. A suitable III-V semiconductor material is in particular indium phosphide (InP) whose lattice constant is about 7.7% greater than that of AlₓGa₁₋ₓP which substantially corresponds to the lattice constant of GaP. In that respect the lattice constant which is greater than GaP (and thus also than AlₓGa₁₋ₓP) simplifies formation of the quantum structures in production of the semiconductor device. As the AlₓG₁₋ₓP is transparent in the visible spectral range the light emitted by the active semiconductor region can pass substantially undisturbed through the semiconductor regions of the semiconductor device. In addition the use of AlₓGa₁₋ₓP makes it possible to implement production of the semiconductor device according to the invention with apparatuses for the production of LEDs based on GaP.

The semiconductor device according to the invention can be in particular in the form of a light emitting diode.

The switching device associated with the semiconductor device can be adapted in particular to output current pulses at a pulse rate which the human eye cannot resolve, and can include an adjusting device for adjusting the pulse rate, wherein the adjusting range is preferably so selected that all pulse rates in the range cannot be resolved by the human eye. With that design configuration, the intensity perceived by a viewer of the light emitted by the semiconductor device according to the invention can be adjusted at a constant pulse duration by the rate of the current pulses. The lower the selected rate, the correspondingly less frequently does the semiconductor device light within a given period of time and the correspondingly lower is then the perceived light intensity of the semiconductor device. Adjustability of the intensity perceived by a viewer is of significance in particular for example if the semiconductor device emits in both emission wavelengths with different levels of intensity or the human eye is less sensitive for one of the wavelengths than for the other wavelength. Such differences can be compensated for with the adjustability of the perceived intensity.

In addition to or alternatively to the adjusting device for adjusting the pulse rate the switching device can also include an adjusting device for adjusting the pulse duration. With that configuration, the intensity perceived by a viewer of the light emitted by the semiconductor device according to the invention, with a constant pulse rate, can be adjusted by the duration of the pulses. If both adjustment options are present, the adjustable range can be increased in comparison with just one adjustment option. When for example the lowest pulse rate is reached, the intensity can be further reduced by reducing the pulse duration.

Preferably the switching device is of such a design configuration that the current intensity outputted at a current pulse can be changed between two current pulses from a current intensity below the threshold current intensity to a current intensity above the threshold current intensity and vice-versa. In that respect a change can be possible either after each current pulse or after a given number of current pulses. That design configuration makes it possible for the light emitted at the different wavelengths, that is to say light of different colors, to be emitted in such a rapidly changing fashion that a viewer cannot resolve the light pulses of different colors. As a consequence of that the semiconductor device, from the point of view of the observer, seems to emit light of a color which represents additive color mixing of the two colors of the alternately emitted light which are referred to hereinafter as basic colors. The proportion of the basic colors in the color mixture can be adjusted by the length of the current pulses of the one basic color in relation to the length of the current pulses of the other basic color and/or the number of the successive current pulses for the one basic color in relation to the number of the successive current pulses for the other basic color. Thus for example, with red and green basic colors, the color yellow is obtained as a mixed color as a consequence of additive color mixing, the resulting yellow shade depending on the mixing ratio of the green and red light.

As the wavelength of the light emitted by the semiconductor device depends not only on the current intensity being above or below the threshold current intensity but otherwise no longer depends on the value of the current intensity, the semiconductor device is particularly suitable for digital actuation of the device.

In the method according to the invention for adjusting the color perceived by a viewer of the light produced by a semiconductor device according to the invention the light of at least two different wavelengths is emitted alternately in pulse form, wherein the change in the wavelength of the emitted light takes place in such a quick succession that the human eye cannot resolve that succession. In a development of the method, adjustment of the mixing ratio of the emitted wavelengths can be effected by the number of the successive pulses of the one wavelength being adjusted in relation to the number of the successive pulses of the other wavelength, or by the duration of the pulses of the one wavelength being adjusted in relation to the duration of the pulses of the other wavelength.

A display device according to the invention includes an array-like arrangement of semiconductor devices according to the invention, in particular light emitting diodes according to the invention. In that respect the switching device can be adapted to output its own switching signal for each semiconductor device of the array so that one switching device is sufficient for all semiconductor devices of the array-like arrangement, or each semiconductor device can have its own switching device associated therewith. The display device according to the invention makes it possible to provide for example displays in which, in particular when using light emitting diodes, the number of lighting elements per pixel can be reduced.

Further features, properties and advantages of the semiconductor device according to the invention will be apparent from the description hereinafter of an embodiment of the invention, with reference to the accompanying drawings.

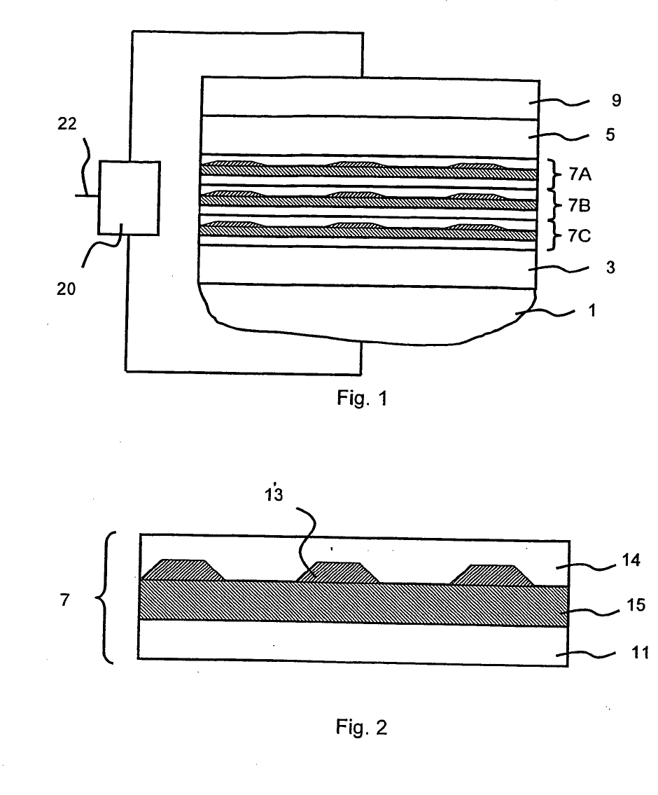

FIG. 1 diagrammatically shows a layer stack implementing the semiconductor device according to the invention,

FIG. 2 shows a view in detail of a portion from the active semiconductor region of the semiconductor device structure shown in FIG. 1,

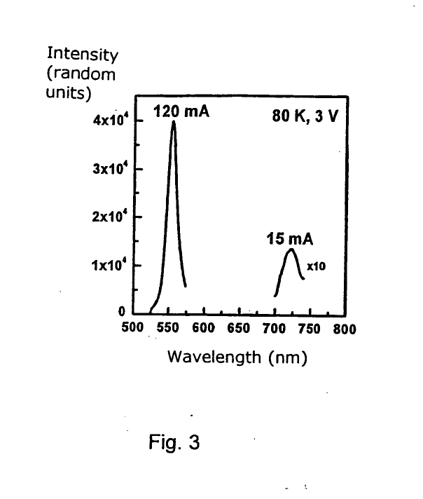

FIG. 3 shows emission spectra of the semiconductor device at different current intensities,

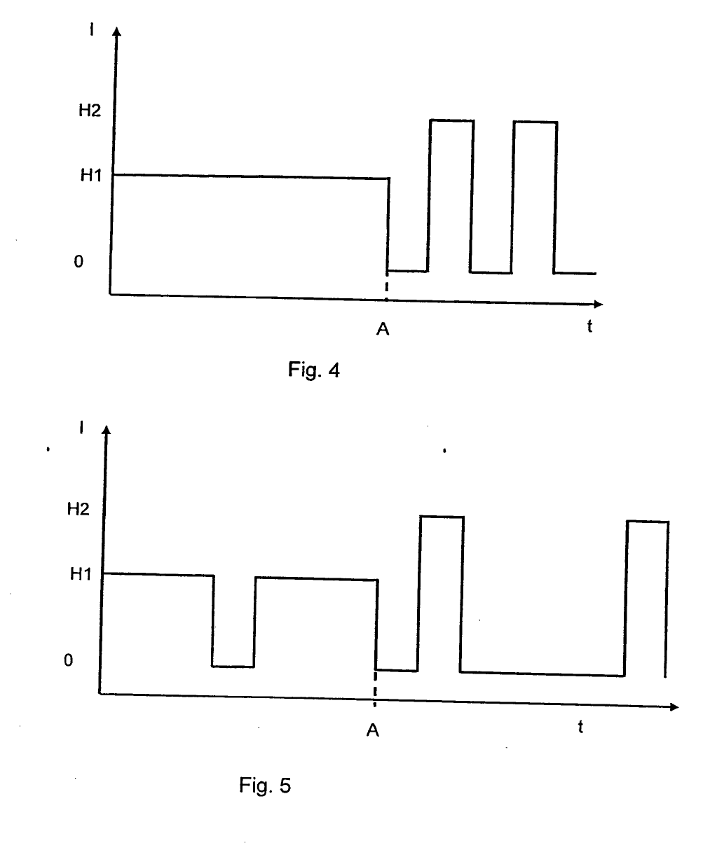

FIG. 4 shows a first pulse diagram for explaining control of light emission,

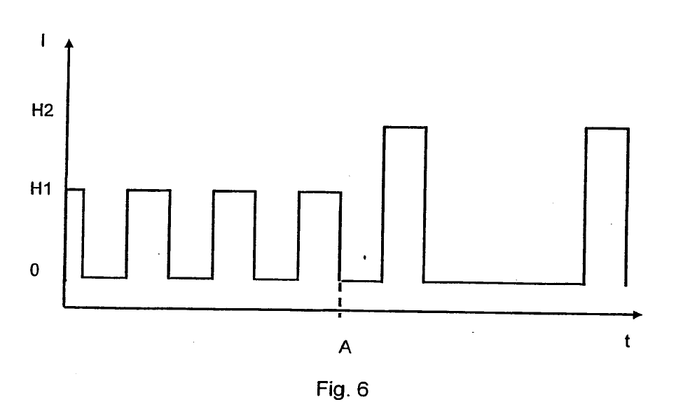

FIG. 5 shows a second pulse diagram for explaining control of light emission,

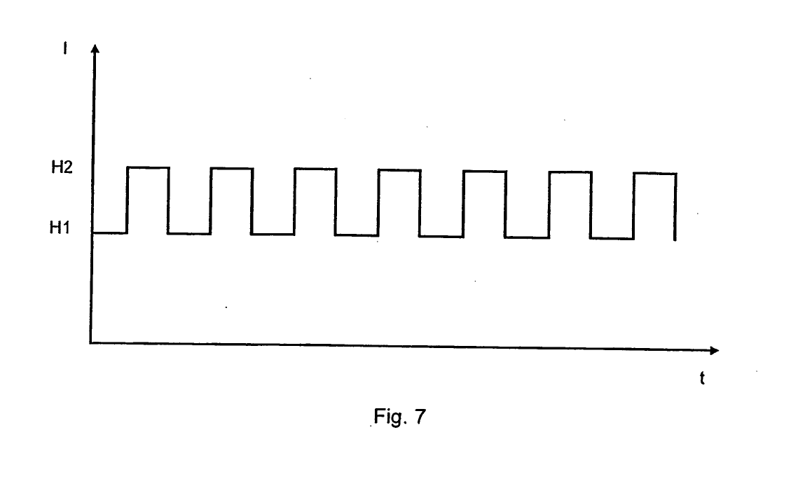

FIG. 6 shows a third pulse diagram for explaining control of light emission, and

FIG. 7 shows a fourth pulse diagram for explaining control of light emission.

FIG. 1 as an embodiment of the semiconductor device according to the invention represents the layer stack of a light emitting diode which is disposed on an n-doped substrate 1. The layer stack includes an n-doped first semiconductor layer 3 which forms a first semiconductor region and a p-doped second semiconductor layer 5 which forms a second semiconductor region. In this respect in the present embodiment the electrons of the n-doped first semiconductor layer 3 represent the charge carriers of the first conductivity type whereas the holes of the p-doped second semiconductor layer 5 represent the charge carriers of the second conductivity type. Arranged between the n-doped first semiconductor layer 3 and the p-doped second semiconductor layer 5 are three undoped quantum structure layers 7A-7C which form the active semiconductor region of the LED. Admittedly in the present embodiment the quantum structure layers 7A-7C are undoped but in alternative configurations of the embodiment they can also have an n-doping or a p-doping. Finally disposed over the second semiconductor layer 5 is a heavily p-doped contact layer 9 for electrically contacting the second semiconductor layer 5.

The substrate 1, the first semiconductor layer 3, the second semiconductor layer 5 and the contact layer 9 are in the form of doped GaP layers. The substrate 1 and the first semiconductor layer 3 each contain silicon (Si) as the dopant, wherein the Si-concentration in the first semiconductor layer 3 corresponds to 5×10¹⁷ cm⁻³. The second semiconductor layer 5 and the contact layer 9 in contrast contain beryllium (Be) as dopant, more specifically in a concentration of 5×10¹⁷ cm⁻³ (second semiconductor layer 5) and 1×10¹⁹ cm⁻³ (contact layer 9) respectively. It should be noted that the dopings of the substrate 1, the first and second semiconductor layers 3, 5 and the contact layer 9 can also be reversed. The semiconductor structure according to the invention would then have a p-doped substrate, a p-doped first semiconductor layer 3, an n-doped second semiconductor layer 5 and an n-doped contact layer 9.

The layer thicknesses are not shown to scale in FIG. 1. While the semiconductor layer 3 is of a thickness of about 200 nm and the semiconductor layer 5 is of a thickness of about 700 nm, the three quantum structure layers 7A-7C together involve only a thickness of between about 18 and 20 nm and the contact layer 9 is of a layer thickness of about 10 nm.

One of the quantum structure layers 7A-7C is shown in detail in FIG. 2. The quantum structure layer 7 includes a GaP layer 11 of a thickness of about 3 nm, to which there is applied an InP wetting layer 15 (referred to as the wetting layer in Stranski-Krastanov growth) which covers the entire surface of the GaP layer 11 and is of a thickness of between 0.1 and 0.3 nm. The InP wetting layer 15 represents a quantum well layer, it is the first configuration of the quantum structures arranged in the quantum structure layer 7. Arranged on the InP wetting layer 15 are InP islands 13 as quantum dots which represent the second configuration of the quantum structures. The InP islands are embedded in a further GaP layer 14 which is also referred to referred to as the GaP matrix. The thickness of the GaP layer matrix 14 is so selected that the InP islands 13 are still covered with GaP, but at a maximum with about 1 nm GaP. In total the thickness of the GaP matrix is about 3 nm so that the total thickness of the quantum structure layer 7 is between about 6 and 6.3 nm.

The lateral dimensions of the InP islands 13 are on average a maximum of about 50 nm. Preferably the average of the lateral dimensions is in the range of between 10 and 30 nm and the coverage of the GaP layer 11 by the InP (InP of the InP wetting layer 15 and the InP islands 13) is about 3.5 ML, that is to say the InP would suffice to cover over the layer therebeneath with about 3.5 monoatomic InP layers. In that respect about 1 ML of the InP is allotted to the wetting layer.

In the present embodiment three quantum structure layers 7A-7C are arranged between the first and second semiconductor layers 3, 5. It is sufficient however if there is one such quantum structure layer 7. On the other hand however there can also be more than only three quantum structure layers. Preferably there are three to five quantum structure layers.

Together with the quantum structure layers 7A-7C, the first and the second semiconductor layers 3, 5 form a light emitting diode. Therein, with a voltage which is suitably applied between the contact layer 9 and the substrate 1 and which is generally referred to as the forward voltage, electrons pass from the first semiconductor layer 3 and holes pass from the second semiconductor layer 5 into the quantum structure layers 7A-7C. Recombination of electrons and holes takes place in the quantum structure layers 7A-7C, that is to say electrons fill the holes. In regard to the electrons that recombination represents a transition from an energy band at a higher energy level into an energy band at a lower energy level. In that respect the transition is a direct transition which takes place substantially in the quantum structures, that is, in the InP. By virtue of the small dimensions of the InP quantum structures the band gap in the InP is much larger than in a large-volume InP material so that the wavelength of the light emitted in the direct transition is in the visible spectral range.

Admittedly, in the described embodiment the substrate 1, the first semiconductor layer 3, the second semiconductor layer 5 and the contact layer 9 are described as GaP layers, but those layers can generally also be in the form of AlₓGa₁₋ₓP layers with 0≦x≦1, wherein the values for x can be different from one layer to another. In a corresponding manner the quantum structures do not need to be made from InP. Instead they can be in the form of In_{y}Ga_{1-y}P layers with 0≦y≦0.5, preferably 0≦y≦0.1. As AlₓGa₁₋ₓP is transparent in the visible spectral range the described layer structure can also be used in particular to produce LEDs which emit vertically, that is to say in the stack direction.

In the described semiconductor structure the wavelength of the emitted light can be influenced by the current intensity of the current flowing through the quantum structure layers 7A-7C. With a forward voltage of 3V and a current intensity of less than about 100 mA the semiconductor device emits red light at a wavelength of about 725 nm whereas at a current intensity of more than about 100 mA it emits green light at a wavelength of about 550 nm (FIG. 3). Experimentally ascertained emission spectra of the described semiconductor structure are illustrated in FIG. 3 for a current intensity of 15 mA and for a current intensity of 120 mA. It will be seen from the Figure that the emission spectrum of the semiconductor device has a maximum at about 725 nm at 15 mA and 3V forward voltage, whereas it has a maximum at about 550 nm at 120 mA and 3V forward voltage.

In both cases the level of intensity of the emitted light is very high by virtue of the direct transition. The semiconductor device also has a similar behaviour at 300 K.

For switching over the current intensity of the current flowing through the active region 7A-7C of the semiconductor structure, associated with the semiconductor device is a switching unit 20 which in the present embodiment is in the form of a digital circuit and which as required feeds the active region 7A-7C with a current at a current intensity of over about 100 mA or at a current intensity of below about 100 mA. The switching unit 20 can be digitally actuated by way of a control input 22 in order to effect switching over between the two current intensities according to the respective requirement involved.

The level of intensity perceived by a viewer of the light emitted by the semiconductor structure can be influenced by suitable control of the operation of switching over the current intensity. It is possible in that way for example to compensate for differences in intensity in the two wavelengths emitted by the semiconductor structure. Compensation can be effected for example by emission being effected continuously at the wavelength at which the level of intensity is lower. If then the device is switched over to emission at the wavelength at which the level of light intensity is higher, that involves changing over to an emission in pulse form. If the low level of light intensity approximately corresponds to half the high level of intensity, the pulses are so selected that a period of the current flow is followed by a period of equal length without a current flow. Such a pulse sequence is shown in FIG. 4. In FIG. 4 the high level H1 represents that current intensity which leads to emission at the one wavelength, the high level H2 represents that current intensity which leads to emission at the other wavelength, and the low level L represents the current intensity at the value zero. The transition from emission at the one wavelength to emission at the other wavelength takes place at the point A.

It will be appreciated that emission at both wavelengths can also be pulsed, in which case the pulses are related to each other in such a way that the duration of the current flow per unit of time in the case of the emissions at low intensity is correspondingly longer than the duration of the current flow per unit of time in the case of the emissions at high intensity. In that case the duration of the current flow per unit of time can be adjusted either by the length of the current pulses (FIG. 5) or the frequency with which the current pulses occur per unit of time, that is to say the pulse rate (FIG. 6). It is also possible for the duration of the current pulses to be influenced by a combination of pulse rate and pulse length.

In a similar manner it is also possible to provide that a viewer perceives a light whose color corresponds to a mixture of the colored light at the one wavelength and the colored light at the other wavelength. That will be described hereinafter with reference to FIG. 7, on the basis of mixing of red and green light. In that respect, for simplification purposes, it is nationally assumed that the emission of the red light and the emission of the green light take place at the same level of light intensity and that a viewer also perceives those intensities as equal. It should be pointed out however that the red light in reality appears more intensive to the viewer than the green light as the human eye is more sensitive to red light than to green light.

Mixing of the colors is effected by a pulsed emission of light, the emission of red light (level H1) alternating with the emission of green light (level H2). In that situation the alternation takes place at a frequency which is so high that the human eye cannot perceive the change. If the level H1 and the level H2 are each of the same duration on the above-indicated assumption, then a viewer perceives light whose color corresponds to an additive mixture of red and green light in a ratio of one to one. Light of that kind is of a yellow color. In that case the ratio of the mixture can be influenced by the ratio of the pulse duration of the level H1 to the pulse duration of the level H2. In reality however the yellow light is not produced by a mixing ratio of one to one but a mixing ratio in which the green light has a greater proportion in order to compensate for the differences in sensitivity of the human eye. That can be achieved for example by the pulse duration for the emission of the green light being selected to be longer than the pulse duration for the emission of the red light.

Alternatively the mixing ratio can also be influenced by respectively using pulses of the same duration, in which case for example the pulses H1 which lead to the emission at the one wavelength occur more frequently than the pulses H2 which lead to the emission at the other wavelength. In that case a respective short pulse without current flow through the semiconductor structure is present between the individual pulses.

If the semiconductor device according to the invention is arranged in an array and the individual semiconductor devices of the array are to be actuated individually, it is possible by means of the semiconductor device to construct a color display in which the number of light-emitting elements can be reduced in comparison with the state of the art as for example red and green light are to be produced with the same semiconductor device.

By means of suitable measures for enclosing the emitted light in the active region of the semiconductor device, for example by a suitable choice in respect of the refractive index of the individual layers or by the provision of facets at the semiconductor structure, it is possible to produce superluminescent diodes emitting incoherent light or laser diodes emitting coherent light, with the semiconductor device according to the invention. The fundamental structure of superluminescent diodes and laser diodes is to be found for example in the books ‘Spontaneous Emission and Laser Oscillation in Microcavities’, Edit. by Hiroyuki Yokoyama and Kikuo Ujihara, CRC Press (1995)’ and ‘Optoelectronics: An Introduction to Material and Devices’, Jasprit Singh, The McGraw-Hill Companies, Inc (1996)’ to which reference is directed in respect of the further configuration of the superluminescent diode according to the invention and the laser diode according to the invention.

1. A semiconductor device for emitting light when a voltage is applied comprising
a first semiconductor region (3) whose conductivity is based on charge carriers of a first conductivity type,
a second semiconductor region (5) whose conductivity is based on charge carriers of a second semiconductor type, which have a charge opposite to the charge carriers of the first conductivity type, and
an active semiconductor region (7A-7C) which is arranged between the first semiconductor region (3) and the second semiconductor region (5), in which quantum structures (13, 15) of a semiconductor material with a direct band gap are embedded in at least two different configurations which are coupled to each other, and
an associated switching device (20) for influencing the current flowing through the active semiconductor region (7A-7C), which is so designed as to switch to and fro at least between a current flow through the active semiconductor region (7A-7C) with a current intensity (H1) below a given threshold current intensity and a current flow through the active semiconductor region with a current intensity (H2) above the threshold current intensity.

2. A semiconductor device as set forth in claim 1 wherein quantum dots (13) are present as a configuration of the quantum structures and a quantum well layer (15) is present as a second configuration of the quantum structures.

3. A semiconductor device as set forth in claim 2 wherein the quantum dots (13) are of a lateral extent which on average is less than about 50 nm.

4. A semiconductor device as set forth in claim 3 wherein the average lateral extent of the quantum structures (13) is in the range of between 10 and 30 nm.

5. A semiconductor device as set forth in claim 1 wherein the semiconductor regions (3, 5, 7A-7C) are embodied in the form of semiconductor layers of a layer stack.

6. A semiconductor device as set forth in claim 1 wherein the first semiconductor region (3), the second semiconductor region (5) and the active semiconductor region (7A-7C) each include AlXGa1_XP with 0<x<1 and the quantum structures (13, 15) are made from a I11-V semiconductor material having a lattice constant which is greater than that of GaP.

7. A semiconductor device as set forth in claim 6 wherein the III-V semiconductor material includes InP.

8. A semiconductor device as set forth in claim 1 wherein the switching device (20) is adapted to output current pulses at a pulse rate which the human eye cannot resolve, and includes an adjusting device for adjusting the pulse rate.

9. A semiconductor device as set forth in claim 1 wherein the switching device (20) includes an adjusting device for adjusting the pulse duration.

10. A semiconductor device as set forth in claim 8 characterised in that the switching device (20) is so designed that the current intensity outputted in the case of a current pulse can be changed between two current pulses from a current intensity (H1) below the threshold current intensity to a current intensity (H2) above the threshold current intensity and vice-versa.

11. A semiconductor device as set forth in claim 1 characterised by being in the form of a light emitting diode.

12. A display device having an array-like arrangement of semiconductor devices as set forth in claim 1.

13. A display device as set forth in claim 12 wherein the switching device is adapted to output for each semiconductor device its own switching signal.

14. A display device as set forth in claim 12 wherein each semiconductor device has its own switching device associated therewith.

15. A method of adjusting the color of the light produced by a semiconductor device as set forth in claim 10, wherein light at at least two different wavelengths is alternately emitted in pulse form and a change in the wavelength of the emitted light takes place in such a rapid succession that the human eye cannot resolve the succession.

16. A method as set forth in claim 15 wherein a mixing ratio of the emitted wavelengths is adjusted by the number of the successive pulses at the one wavelength being adjusted in relation to the number of the successive pulses at the other wavelength.

17. A method as set forth in claim 15 wherein a mixing ratio of the emitted wavelengths is adjusted by the duration of the pulses at the one wavelength being adjusted in relation to the duration of the pulses at the other wavelength.
